(19) United States
(12) Patent Application Publication
(10) Pub. No.: US 2007/0246195 A1
(43) Pub. Date: Oct. 25, 2007

(54) Orientation insensitive thermosiphon with squirrel cage configuration

(76) Inventors: Mohinder Singh Bhatti, Amherst, NY (US); Ilya Reyzin, Williamsville, NY (US); Shrikant Mukund Joshi, Williamsville, NY (US)

Correspondence Address: DELPHI TECHNOLOGIES, INC., M/C 480-410-202, PO BOX 5052, TROY, MI, 48007, US

(21) Appl. No.: 11/406,617

(22) Filed: Apr. 19, 2006

(51) Int. Cl. H05K 7/20

(52) U.S. Cl. 165/104.33; 165/80.3; 361/700

(57) ABSTRACT

An orientation insensitive heat exchanger assembly includes a housing having an upper portion including condensing tubes extending upwardly and intersecting a top wall of the lower portion. The condensing tubes are spaced equally from one another circumferentially and radially from the central axis and extend outwardly at a predetermined angle from the central axis. A fan assembly is disposed along a central axis extending upwardly from a center of the housing wherein the condensing tubes surround the fan assembly and the fan moves air radially out through the spaces between the condensing tubes.

### CROSS REFERENCE TO RELATED APPLICATION

This application discloses and claims the configuration of disposing condensing tubes circumferentially about an axis. Co-pending application Ser. No. ______ filed ______ (DP-314802, 604080-00019) discloses and claims the one patentably distinct concept of mixing in the refrigerant cycle but illustrates that concept in the configuration of the instant application.

### BACKGROUND OF THE INVENTION

1. Field of the Invention

The present invention relates to an orientation insensitive heat exchanger assembly for cooling an electronic device.

2. Description of the Prior Art

The operating speed of computers is constantly being improved to create faster computers. With this, comes increased heat generation and a need to effectively dissipate that heat. As laptop computers become more universal, the ability to position these heat exchangers and other parts in any one of numerous orientations becomes of greater importance.

Heat exchangers and heat sink assemblies have been used that apply natural or forced convection cooling methods to dissipate heat from electronic devices that are highly concentrated heat sources such as microprocessors and computer chips; however, air has a relatively low heat capacity. Thus, liquid-cooled units called LCUs employing a cold plate in conjunction with high heat capacity fluids have been used to remove heat from these types of heat sources. Although, LCUs are satisfactory for moderate heat flux, increasing computing speeds have required more effective heat sink assemblies.

Accordingly, thermosiphon cooling units (TCUS) have been used for cooling electronic devices having a high heat flux. A typical TCU absorbs heat generated by the electronic device by vaporizing a working fluid housed on the boiler plate of the unit. The boiling of the working fluid constitutes a phase change from liquid-to-vapor state and as such the working fluid of the TCU is considered to be a two-phase fluid. Vapor generated during boiling of the working fluid is then transferred to a condenser, where it is liquefied by the process of film condensation over the condensing surface of the TCU. The heat is rejected into a stream of air flowing over fins extending from the condenser and the condensed liquid is returned back to the boiler plate by gravity. As a result, most TCUs must be positioned in a predetermined orientation in order for the refrigerant to continue the boiling-condensing cycle, thus making the TCU orientation sensitive.

To solve this problem orientation insensitive thermosiphons have been used. Examples of such thermosiphons include U.S. Pat. No. 6,695,039 to Reyzin et al., U.S. Pat. No. 6,918,431 to Reyzin et al., and U.S. Pat. No. 6,085,831 to DiGiacomo et al.

The '039 patent is a thermosiphon assembly including a housing having a lower portion for holding a refrigerant for liquid-to-vapor transformation and an upper chamber, and heat transfer fins disposed in the lower portion. The upper portion of the housing includes one chamber extending upwardly at an angle such that the thermosiphon can operate in both a vertical and a horizontal position and any angle of tilt therebetween. However, the assembly cannot be rotated a full revolution while in a tilted or horizontal position and remain operational.

The '831 patent is a thermosiphon including a housing having a lower portion for holding a refrigerant and an upper portion having a top wall wherein heat transfer fins are disposed on the top wall. The upper portion of the housing includes a plurality of condensing chambers extending upwardly and outwardly along a single vertical plane from the lower portion of the housing. In this arrangement, the assembly is operational in both the vertical and horizontal orientations; however, the assembly is not operational when tilted about its central axis in the horizontal position.

The '431 patent includes a housing having an upper portion and a lower portion wherein the upper portion is a single condensing chamber extending upwardly and outwardly from the lower portion in a conical shape.

Although the prior art dissipates heat from electronic devices at a variety of orientations, as laptop computers gains prominence, orientation-insensitivity becomes of growing importance and thus there is a continuing need to have heat exchanger assemblies operable in more orientations than conventional orientation insensitive heat exchanger assemblies.

### SUMMARY OF THE INVENTION AND ADVANTAGES

The invention provides an orientation insensitive heat exchanger assembly for cooling an electronic device comprising a housing having an upper portion and a lower portion disposed about a central axis extending upwardly from a center of the housing. The lower portion includes a top wall and houses a refrigerant for liquid-to-vapor transformation and the upper portion includes a plurality of condensing tubes intersecting the top wall of the lower portion of the housing and extending upwardly therefrom. At least three of the condensing tubes are spaced equally from one another circumferentially about and radially from the central axis.

The assembly of the present invention is suitable for operation not only in the horizontal and vertical orientations, but additionally at any angle of tilt therebetween. Furthermore, the assembly can operate at any angle of rotation about a central axis in addition to the angle of tilt. The assembly also offers a compact arrangement having the fan assembly centrally located while simultaneously providing enhancement of heat transfer through the use of louvered fins.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is perspective view of the preferred embodiment of the invention in a vertical position;

FIG. 2 is a cross-sectional view of the embodiment shown in FIG. 1; and

FIG. 3 is a cross-sectional view of the embodiment shown in FIGS. 1 and 2 in a horizontal position.

### DETAILED DESCRIPTION OF THE INVENTION

Referring to the Figures, wherein like numerals indicate corresponding parts throughout the several views, an orientation insensitive heat exchanger assembly 20 is generally shown for cooling an electronic device 22.

The assembly 20 includes a housing 24 generally indicated having an upper portion 26 and a lower portion 28 disposed about a central axis 30 extending upwardly from a center of the housing 24.

The lower portion 28 includes a top wall 32 and the upper portion 26 includes a plurality of condensing tubes 34 intersecting the top wall 32 of the lower portion 28 of the housing 24. The condensing tubes 34 extend in a circle about the central axis 30. The condensing tubes 34 have a uniform circular cross-section but can have a non-uniform or noncircular cross-section such as a rectangular cross-section.

A refrigerant 36 is disposed in the lower portion 28 of the housing 24 for liquid-to-vapor transformation and a plurality of first heat transfer fins 38 are disposed in the lower portion 28 for enhancing heat transfer from the electronic device 22 disposed on the exterior of the lower portion 28 of the housing 24 to the refrigerant 36.

A plurality of second heat transfer fins 40 are disposed on the top wall 32 of the lower portion 28 of the housing 24 for dissipating heat from the refrigerant 36 in the lower portion 28 of the housing 24. The second heat transfer fins 40 extend radially from the central axis 30 toward the condensing tubes 34.

A fan assembly 42 generally indicated is disposed along the axis 30 whereby the condensing tubes 34 surround the fan assembly 42. The fan assembly 42 is a centrifugal fan and moves air radially outwardly through the spaces between the condensing tubes 34 surrounding the fan assembly 42 for dissipating heat from the condensing tubes 34.

The fan assembly 42 includes a shaft 44 extending along the axis 30 upwardly from the center of the upper portion 26 of the housing 24, a plurality of fan blades 46 disposed about the shaft 44 for moving air radially, and a motor 48 disposed on a top portion 50 of the shaft 44 for rotating the shaft 44. The fan blades 46 are elongated vertical panels 52 supported by intermittent circumferential panels 54 interconnecting the elongated vertical panels 52 forming a fence-like and cylindrical enclosure around the shaft 44 whereby air is drawn axially into the cylindrical fan and radially toward the condensing tubes 34.

A cage cover 56 is disposed on the condensing tubes 34 for supporting the fan assembly 42 and includes openings for allowing outside air to flow into the fan assembly 42. The cage cover 56 also attaches to top ends 58 of the condenser tubes.

A plurality of louvered fins 60 extend between the condensing tubes 34 for dissipating heat from the condensing tubes 34 to ambient air moved over the louvered fins 60 by the fan assembly 42. The louvered fins 60 are convoluted and extend the full length of the condensing tubes 34. Each louvered fin 60 has slits extending thereacross, which are serial as shown in the Figures, but may be continuous.

The assembly 20 is distinguished by including at least three of the condensing tubes 34 spaced equally no less than one hundred and twenty degrees from one another circumferentially about and radially from the axis 30. The preferred embodiment illustrated in the figures, defines an octagon with eight condensing tubes 34. The condensing tubes 34 extend upwardly and outwardly at a predetermined angle relative to the axis 30 to the top ends 58 of the condensing tubes 34 whereby bottom ends 62 of the condensing tubes 34 are closer to the axis 30 than the top ends 58 of the condensing tubes 34.

When operating, the electronic device 22 generates an amount of heat to be dissipated. The heat is transferred from the electronic device 22 to the lower portion 28 of the housing 24 and thereafter from the first heat transfer fins 38 into the refrigerant 36 disposed in the lower portion 28 of the housing 24 causing the refrigerant 36 to boil. Vapor boiled off of the refrigerant 36 rises into the condensing tubes 34 due to gravity. Heat is transferred from the vapor in the condensing tubes 34 into the upper portion 26 of the housing 24 and thereafter from the louvered fins 60 connected to the condensing tubes 34 into the air flowing across each fin from the fan assembly 42. The vapor condenses on inside walls of the condensing tubes 34 and moves back into the lower portion 28 of the housing 24 by gravity to continue the boiling-condensing cycle.

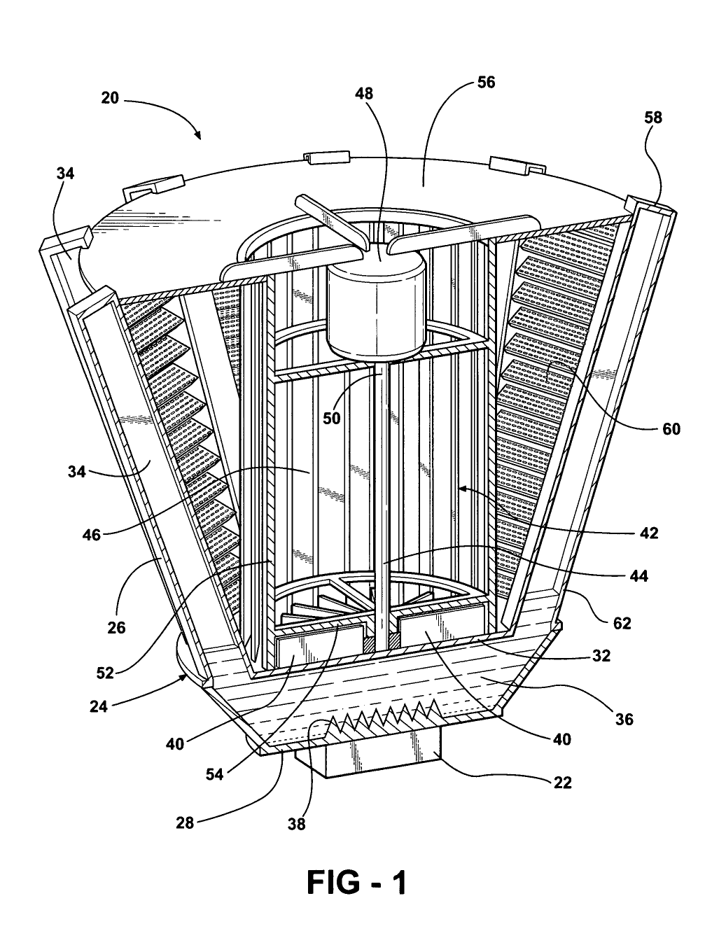

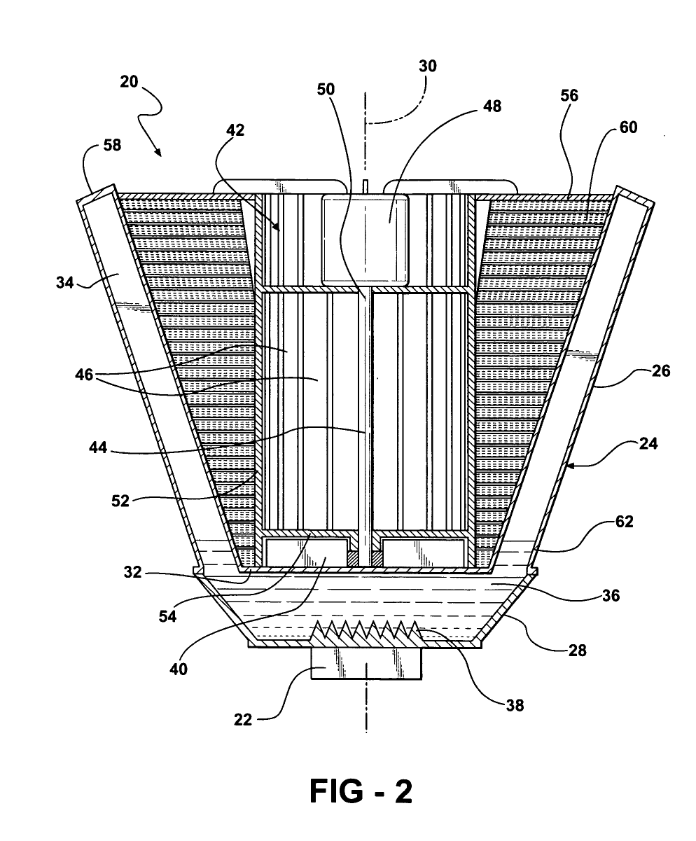

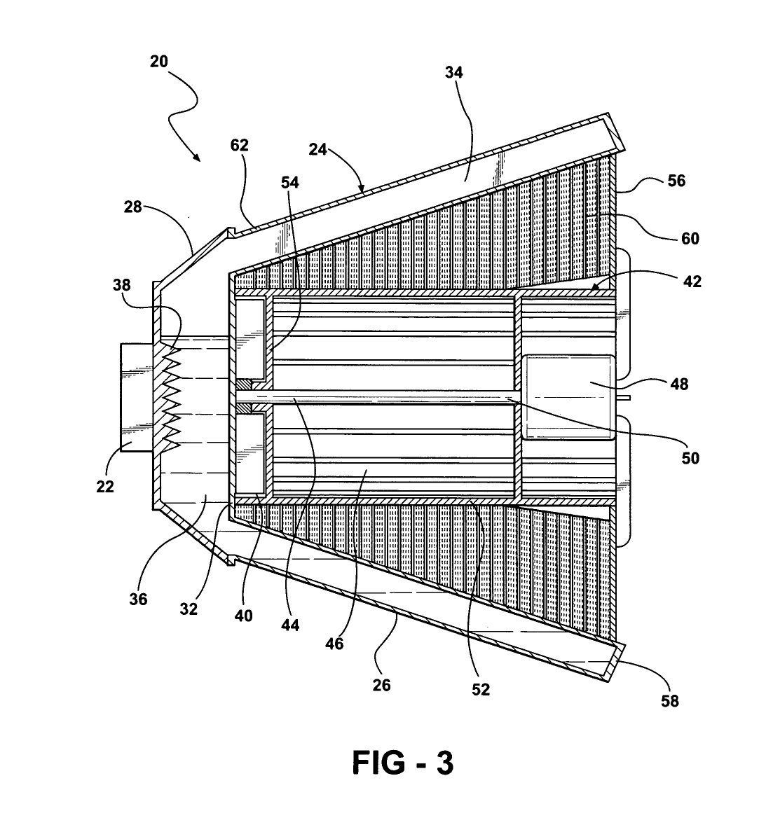

When the assembly 20 is positioned vertically as shown in FIGS. 1 and 2, the vapor travels into all of the condensing tubes 34. However, when the assembly 20 is tilted or positioned horizontally as shown in FIG. 3, the vapor travels into only the condensing tubes 34 extending upwardly and above the liquid refrigerant 36 level. In a vertical position, horizontal position and all instances therebetween, the assembly 20 can be rotated about the central axis 30 and continue to have at least one condensing tube 34 extending upwardly such that the refrigerant 36 can continue the boiling-condensing cycle.

Obviously, many modifications and variations of the present invention are possible in light of the above teachings. The invention may be practiced otherwise than as specifically described within the scope of the appended claims.

What is claimed is:

1. An orientation insensitive heat exchanger assembly for cooling an electronic device comprising;
a housing having an upper portion and a lower portion disposed about a central axis extending upwardly from a center of said housing,
said lower portion including a top wall,
said upper portion including a plurality of condensing tubes intersecting said top wall of said lower portion of said housing and extending upwardly,
a refrigerant disposed in said lower portion of said housing for liquid-to-vapor transformation, and
at least three of said condensing tubes spaced equally from one another circumferentially about and radially from said axis.

2. An assembly as set forth in claim 1 including a fan assembly disposed along said axis for moving air radially outwardly through the spaces between said condensing tubes surrounding said fan assembly.

3. An assembly as set forth in claim 2 including a plurality of louvered fins extending between adjacent of said condensing tubes for dissipating heat from said condensing tubes to ambient air moved over said louvered fins by said fan assembly.

4. An assembly as set forth in claim 3 including a plurality of first heat transfer fins disposed in said lower portion of said housing for transferring heat from the electronic device disposed on the exterior of said lower portion of said housing to said refrigerant.

5. An assembly as set forth in claim 3 including a plurality of second heat transfer fins disposed on said top wall of said lower portion of said housing extending radially from said central axis toward said condensing tubes for dissipating heat from said refrigerant in said lower portion of said housing.

6. An assembly as set forth in claim 1 wherein said condensing tubes extend upwardly and outwardly at a predetermined angle relative to said axis to top ends of said condensing tubes whereby bottom ends of said condensing tubes are closer to said axis than said top ends of said condensing tubes.

7. An assembly as set forth in claim 3 including a cage cover disposed on said condensing tubes for supporting said fan assembly.

8. An assembly as set forth in claim 7 wherein said fan assembly includes a shaft extending along said axis upwardly from said center of said upper portion of said housing, a plurality of fan blades disposed about said shaft for moving air radially, and a motor disposed on a top portion of said shaft for rotating said shaft and supported by said cage cover.

9. An assembly as set forth in claim 6 including a plurality of second heat transfer fins disposed on said top wall of said lower portion of said housing extending radially from said axis toward said condensing tubes for dissipating heat from said refrigerant in said lower portion of said housing.

10. An assembly as set forth in claim 6 including a plurality of louvered fins extending between said condensing tubes for dissipating heat from said condensing tubes to ambient air.

11. An assembly as set forth in claim 10 including a fan assembly for moving air radially through said louvered fins.

12. An assembly as set forth in claim 11 including a cage cover disposed on said condensing tubes for supporting said fan assembly.

13. An orientation insensitive heat exchanger assembly for cooling an electronic device comprising;
a housing having an upper portion and a lower portion disposed about a central axis,
said lower portion having a top wall,
said upper portion including a plurality of condensing tubes extending upwardly from bottom ends intersecting said top wall of said lower portion of said housing,
a refrigerant disposed in said lower portion of said housing for liquid-to-vapor transformation,
a plurality of first heat transfer fins disposed in said lower portion of said housing for enhancing heat transfer from the electronic device disposed on the exterior of said lower portion of said housing to said refrigerant,
a plurality of second heat transfer fins disposed on said top wall of said lower portion of said housing and extending radially from said central axis toward said condensing tubes for dissipating heat from said refrigerant in said lower portion of said housing,
a plurality of louvered fins extending between adjacent of said condensing tubes for dissipating heat from said condensing tubes to ambient air,
said condensing tubes spaced equally from one another circumferentially about and radially from said central axis and extending upwardly and outwardly at a predetermined angle from said axis to top ends of said condensing tubes whereby said bottom ends of said condensing tubes are closer to said axis than said top ends of said condensing tubes,
said condensing tubes and said louvered fins forming an octagon,
a fan assembly for blowing air radially through said louvered fins,
said fan assembly being a centrifugal fan and including a shaft extending along said axis upwardly from said center of said upper portion of said housing and a plurality of fan blades disposed about said shaft for blowing air radially and a motor disposed on a top portion of said shaft for rotating said shaft, and
a cage cover disposed on said top ends of said condensing tubes for supporting said motor.
